(19) United States
(12) Patent Application Publication
(10) Pub. No.: US 2006/0158105 A1
(43) Pub. Date: Jul. 20, 2006

(54) Organic light emitting device and method for preparing the same

(76) Inventors: Mu-Gyeom Kim, Hwaseong-si (KR); In-Nam Kang, Ansan-si (KR); Sang-Yeol Kim, Gwacheon-si (KR); Tae-Woo Lee, Seoul (KR)

Correspondence Address: Robert E. Bushnell, Suite 300, 1522 K Street, N.W., Washington, DC, 20005, US

(21) Appl. No.: 11/328,157

(22) Filed: Jan. 10, 2006

(30) Foreign Application Priority Data
Jan. 20, 2005 (KR) 10-2005-0005529

(51) Int. Cl. H01L 51/54; H05B 33/12; H01L 51/56

(52) U.S. Cl. 313/504; 428/690; 428/917; 428/212; 313/506; 427/66

(57) ABSTRACT

An organic light emitting device including a first electrode; a second electrode; and an organic layer that is interposed between the two electrodes and has at least a luminescent layer, wherein the luminescent layer includes a first luminescent layer and a second luminescent layer, and an exciton pinning layer interposed between the first luminescent layer and the second luminescent layer is provided.

### CROSS-REFERENCE TO RELATED PATENT APPLICATION

This application claims the benefit of Korean Patent Application No. 10-20050005529, filed on Jan. 20, 2005, in the Korean Intellectual Property Office, the disclosure of which is incorporated herein in its entirety by reference.

### BACKGROUND OF THE INVENTION

1. Field of the Invention

The present invention relates to an organic light emitting device and a method for preparing the same. More specifically, the present invention relates to an organic light emitting device having a luminescent layer and an exciton pinning layer and a method for preparing the same.

2. Description of the Related Art

An organic light emitting device is a self-emission device which emits light when an electronic transition of the excitons formed by combination of electrons and holes is made from the excited state to the ground state. And, since an organic light emitting device has various advantages such as light weight, a simple structure which can be made by uncomplicated manufacturing process, a large view angle, high brightness, full-color, low power consumption, low voltage-driving and a complete expression of moving picture, the device is very useful in portable electronic devices.

An organic light emitting device can be divided into a small molecular organic light emitting device (SMOLED) and a polymer organic light emitting device (PLED), depending on the molecular weight of the material forming a luminescent layer.

In many cases of the small molecular organic light emitting device, an organic layer including at least a luminescent layer has a multi-layer structure that further comprises a hole injection layer, a hole transport layer, an electron transport layer and/or an electron injection layer and the like to allow holes and electrons to move effectively. The layers can be formed by vacuum thermal deposition technique, vapor phase deposition technique or coating technique and the like.

Contrary to the small molecular organic light emitting device, the polymer organic light emitting device has advantages in that mechanical strength and thermal stability of the organic layer interposed between electrodes are high, a driving voltage is low, and various emitting colors can be obtained by various molecular structures of the luminescent polymer. Such an organic layer of the polymer OLED can be formed by coating a solution composed of luminescent polymer solved in suitable organic solvent, using coating techniques such as spin casting, ink jet printing and the like.

Basically, the organic light emitting device such as a SMOLED and a PLED as described above comprises a first electrode and a second electrode that can transport holes and electrons, and a luminescent layer interposed between the first electrode and the second electrode. The holes and the electrons combine in the luminescent layer to form excitons, and the light emission occurs by an electronic transition of the excitons from the excited state to the ground state. The studies intended to improve efficiency and lifetime of the organic light emitting device have been progressed extensively by controlling such excitons.

For example, U.S. Pat. No. 6,451,415 B1 to S. R. Forrest et al. discloses an organic photosensitive optoelectronic device having an exciton-blocking layer. In this patent, it is disclosed that the exciton blocking layer plays a role to prevent exciton diffusion into an electron transport layer and a charge transport layer. Also, the exciton-blocking layer is located in the electron transport layer or adjacent to the electron transport layer. Therefore, the exciton zone exits over the layers forming the organic photosensitive optoelectronic device.

However, since the prior art cannot provide an organic light emitting device with satisfactory lifetime, there is an urgent need to provide an organic light emitting device with improved lifetime.

### SUMMARY OF THE INVENTION

It is an object of the present invention to solve the problems of the prior art.

It is also an object of the present invention to provide an improved organic light emitting device.

The present invention provides an improved organic light emitting device having a luminescent layer which includes a first luminescent layer and a second luminescent layer, and an exciton pinning layer interposed between the first luminescent layer and the second luminescent layer.

The present invention also provides a method for preparing the organic light emitting device.

According to an aspect of the present invention, there is provided an organic light emitting device, including a first electrode; a second electrode; and an organic layer that is interposed between the first electrode and the second electrode and includes at least a luminescent layer, wherein the luminescent layer comprises a first luminescent layer and a second luminescent layer, and an exciton pinning layer which is interposed between the first luminescent layer and the second luminescent layer.

According to another aspect of the present invention, there is provided a method for preparing the organic light emitting device, including forming a first electrode on a substrate; forming an organic layer on the first electrode; and forming a second electrode on the organic layer, wherein the step of forming the organic layer includes forming a first luminescent layer; forming an exciton pinning layer on the first luminescent layer; forming a second luminescent layer on the exciton pinning layer.

According to another aspect of the present invention, there is provided an organic light emitting device, including: a first electrode; a second electrode; and an organic layer interposed between the first electrode and the second electrode, the organic layer having at least a luminescent layer comprising a first luminescent layer formed of a first material and a second luminescent layer formed of a second material, and an exciton pinning layer interposed between the first luminescent layer and the second luminescent layer, the exciton pinning layer formed of a third material, the third material meeting at least one of the following conditions: (1) a HOMO (the highest occupied molecular orbital) level of the third material being lower than a HOMO level of the first material and a HOMO level of the second material; and (2) a LUMO level (the lowest unoccupied molecular orbital) of the third material being lower than a LUMO level of the first material and a LUMO level of the second material.

Since the organic light emitting device of the present invention may have significantly improved lifetime. Additionally, lifetime of the organic light emitting device can be controlled by adjusting the position of the exciton pinning layer in the luminescent layer.

### BRIEF DESCRIPTION OF THE DRAWINGS

A more complete appreciation of the present invention, and many of the above and other features and advantages of the present invention, will be readily apparent as the same becomes better understood by reference to the following detailed description when considered in conjunction with the accompanying drawings in which like reference symbols indicate the same or similar components, wherein:

FIG. 1 is an energy band diagram that illustrates the difference of a HOMO level and a LUMO level of layers constituting an organic layer of the organic light emitting device according to an embodiment of the present invention;

FIG. 2 illustrates a structure of an organic layer of the organic light emitting device of an embodiment of the present invention; and

FIG. 3 is a graph that shows lifetime properties of organic layers of the organic light emitting devices according to embodiments of the present invention.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. Like numbers refer to like elements throughout the specification.

The organic light emitting device according to the present invention includes a first electrode, a second electrode, and an organic layer that is interposed between the first electrode and the second electrode and includes at least a luminescent layer and an exciton pinning layer. The luminescent layer includes the first luminescent layer and the second luminescent layer, and the exciton pinning layer is interposed between the first luminescent layer and the second luminescent layer.

The exciton pinning layer plays a role in pinning recombination region in the luminescent layer that has significantly high density of excitons. Therefore, high light emitting efficiency has achieved even at a low current, since the light emitting occurs at the region that has high exciton density in the luminescent layer. Also, since surplus currents that do not take part in emitting decrease due to high efficiency emitting by the exciton pinning layer as described above, the thermal damage of the luminescent layer due to the surplus currents can be minimized. Additionally, since the emitting occurs in the exciton pinning layer interposed between the first luminescent layer the second luminescent layer and exciton movement toward the vicinity of the electrode decreases, an exciton quenching effect that occurs at the vicinity of the electrode can be reduced. Accordingly, the lifetime of an organic light emitting device can be improved by such a mechanism. Additionally, according to the mechanism, the lifetime of an organic light emitting device can be controlled by adjusting a position of the exciton pinning layer in the luminescent layer.

For controlling the lifetime, a HOMO (the highest occupied molecular orbital) level and/or a lower LUMO (the lowest unoccupied molecular orbital) level of the material forming an exciton pinning layer than a HOMO level and/or a LUMO level, respectively, of the material forming the first and second luminescent layers. That is, at least one of the HOMO level and the LUMO level of the exciton pinning layer material is lower than that of the first and second luminescent layers material. Accordingly, there is a region (i.e. exciton pinning layer) having a HOMO level and/or a LUMO level lower than a HOMO level and/or a LUMO level of adjacent regions.

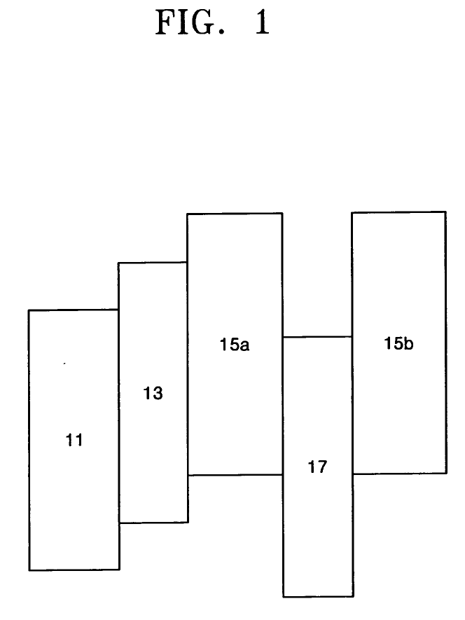

The energy band diagram of the organic layer comprising the luminescent layer and the exciton pinning layer interposed between a first luminescent layer and a second luminescent layer is illustrated in FIG. 1.

FIG. 1 is an energy band diagram of the organic layer having a structure laminated by a hole injection layer 11, a hole transport layer 13, a first luminescent layer 15a, an exciton pinning layer 17 and a second luminescent layer 15b sequentially and shows the difference of a HOMO level and a LUMO level of each layers.

With reference to FIG. 1, the first luminescent layer 15a and the second luminescent layer have the same HOMO level and the same LUMO level. A HOMO level and a LUMO level of the exciton pinning layer interposed between the first luminescent layer 15a and the second luminescent layer are lower than a HOMO level and a LUMO level, respectively, of the first and second luminescent layers. Accordingly, the exciton formed by combining holes transferred to the first luminescent layer 15a via the hole injection layer 11 and the hole transport layer 13 and the electrons transferred to the second luminescent layer 15b from the electron injection layer (not shown) can be pinned in the exciton pinning layer 17 to increase the exciton density. Since the HOMO level and the LUMO level of the material forming the exciton pinning layer are lower than the HOMO level and the LUMO level, respectively, of the material forming the first luminescent layer and the second luminescent layer adjacent to the exciton pinning layer, as described in FIG. 1.

Herein, for describing the exciton pinning layer and the luminescent layer of the organic light emitting device, the terms “the first luminescent layer” and “the second luminescent layer” are used to illustrate two respective regions of the luminescent layer that are divided into by the exciton pinning layer. The term “the first luminescent layer” is referred to the region of the luminescent layer that is located between the first electrode and the exciton pinning layer. The term “the second luminescent layer” is referred to the region of the luminescent layer that is located between the second electrode and the exciton pinning layer.

The material forming the first luminescent layer (“first luminescent layer material”) and the materials forming the second luminescent layer (“second luminescent layer material”) can be the same. In this case, after forming the first luminescent layer and the exciton pinning layer, the second luminescent layer is formed of the same material as the first luminescent layer material. The HOMO level, the LUMO level, or both of the HOMO level and the LUMO level of the exciton pinning layer material according to the present invention can be lower than the HOMO level, the LUMO level, or both of the HOMO level and the LUMO level, respectively, of the first and second luminescent layer material.

More specifically, when the first luminescent layer material and the second luminescent layer material are the same, the HOMO level of the exciton pinning layer material can be lower than the HOMO level of the material forming the first and second luminescent layers. Alternatively, the LUMO level of the exciton pinning layer material can be lower than the LUMO level of the material forming the first and second luminescent layers. Alternatively, both of the HOMO level and the LUMO level of the exciton pinning layer material can be lower than the HOMO level and the LUMO level of the material forming the first and second luminescent layers.

The first luminescent layer material and the second luminescent layer material can be different from each other, for example, for the control of the total energy band gap of the luminescent layer including the exciton pinning layer, color tuning and the like. That is, after forming the first luminescent layer and the exciton pinning layer, the second luminescent layer can be formed of the material different from the first luminescent layer material. The HOMO level, the LUMO level, or both of the HOMO level and the LUMO level of the exciton pinning layer material should be lower than the HOMO levels, a LUMO levels or both of the HOMO levels and the LUMO levels of the first luminescent layer material and the second luminescent layer material.

More specifically, when the first luminescent layer material and the second luminescent layer material are different from each other, the HOMO level of the exciton pinning layer material can be lower than the HOMO level of the first luminescent layer material and a HOMO level of the second luminescent layer material. Also, the LUMO level of the exciton pinning layer material can be lower than the LUMO level of the first luminescent layer material and the LUMO level of the second luminescent layer material. Also, both the HOMO level and the LUMO level of the material forming the exciton pinning layer can be lower than both the HOMO level and the LUMO level of the first luminescent layer material and both the HOMO level and the LUMO level of the second luminescent layer material.

Taking account into the difference of the HOMO levels and/or the LUMO levels between the exciton pinning layer material and the first and second luminescent layer materials, the exciton pinning layer material and the first and second luminescent layer materials can be selected from the materials that emit the same color or different colors. For example, when the first and second luminescent layers are formed of blue luminescent materials, the exciton pinning layer can be formed of blue luminescent material that have a lower HOMO level and/or a LUMO level than a HOMO level and/or a LUMO level of the blue luminescent material forming the first and second luminescent layers. This is applicable to the cases where the first and second luminescent layers are formed of red luminescent material or green luminescent material. Alternatively, when the first and second luminescent layers are formed of blue luminescent material, the exciton pinning layer can be formed of green luminescent material or red luminescent material. Also, when the first and second luminescent layers are formed of green luminescent material, the exciton pinning layer can be formed of red luminescent material. This uses the common concept of that the HOMO level and/or the LUMO level of the blue luminescent material are higher than the HOMO level and/or the LUMO level of the green luminescent material, and the HOMO level and/or the LUMO level of the green luminescent material are higher than the HOMO level and/or the LUMO level of the red luminescent material.

A thickness of the exciton pinning layer can be varied depending on the exciton pinning layer material. The thickness of the exciton pinning layer is preferably 10 nm to 40 nm. When the thickness of the exciton pinning layer is lower than 10 nm, sufficient exciton pinning effect cannot be obtained. When the thickness of the exciton pinning layer is more than 40 nm, a color of light emitted from the luminescent layer can be different from the desired color, since excitons are trapped in the luminescent layer rather than are pinned.

The sum of the thickness of the first luminescent layer and the thickness of the second luminescent layer can be varied depending on the materials forming the luminescent layer. The sum of the thickness of the first luminescent layer and the thickness of the second luminescent layer is preferably 50 nm to 100 nm. When the sum is more than 100 nm, the reduction of lifetime due to efficiency reduction can be expected.

The materials forming the exciton pinning layer are not limited to particular materials, provided that the materials fulfill all the conditions as described above such as a HOMO level and/or a LUMO level. For example, as the blue luminescent material forming the exciton pinning layer, oxadiazole dimer dyes (Bis-DAPOXP), spiro compounds (Spiro-DPVBi, Spiro-6P), triarylamine compounds, bis(styryl)amine (DPVBi, DSA), bis[2-(4,6-difluorophenyl)pyridinato-N,C^{2′}] iridium picolinate (Flrpic), CzTT, Anthracene, 1,1,4,4-tetraphenyl-1,3-butadiene (TPB), 3,5,3′,5′-tetrakis-tert-butyldiphenoquione; 1,2,3,4,5-pentaphenyl-1,3-cyclopentadiene (PPCP), DST, TPA, OXD-4, BBOT, AZM-Zn, etc. can be used. The examples of the green luminescent material forming the exciton pinning layer include Coumarin 6, C545T, Quinacridone, Ir(ppy)₃, etc. The examples of the red luminescent material forming the exciton pinning layer include DCM1, DCM2, Eu(thenoyltrifluoroacetone)₃ (Eu(TTA)₃), butyl-6-(1,1,7,7-tetramethyljulolidyl-9-enyl)-4H-pyran (DCJTB) etc. Also, the materials can be one or more selected from polyphenylenevinylene (PPV) based polymer and derivatives thereof, polyphenylene (PPP) based polymer and derivatives thereof, polythiophene (PT) based polymer and derivatives thereof, polyfluorene (PF) based polymer and derivatives thereof and polyspirofluorene (PSF) based polymer and derivatives thereof. Polyfluorene (PF) based polymer and derivatives thereof are preferable.

The materials forming the first and second luminescent layers are not limited to particular materials, and common materials for forming the luminescent layer can be used. However, the materials should fulfill all the conditions as described above such as a HOMO level, a LUMO level and both. For example, as the blue luminescent material forming the first and second luminescent layers, oxadiazole dimer dyes (Bis-DAPOXP), spiro compounds (Spiro-DPVBi, Spiro-6P), triarylamine compounds, bis(styryl)amine (DPVBi, DSA), Flrpic, CzTT, Anthracene, TPB, PPCP, DST, TPA, OXD-4, BBOT, AZM-Zn etc. can be used. The examples of the green luminescent material forming the exciton pinning layer include Coumarin 6, C545T, Quinacridone, Ir(ppy)₃ etc. The examples of the red luminescent material forming the exciton pinning layer include DCM1, DCM2, Eu(thenoyltrifluoroacetone)₃ (Eu(TTA)₃), butyl-6-(1,1,7,7-tetramethyljulolidyl-9-enyl)-4H-pyran (DCJTB) etc. Also, the materials can be one or more materials selected from the group consisting of polyphenylenevinylene (PPV) based polymer and derivatives thereof, polyphenylene (PPP) based polymer and derivatives thereof, polythiophene (PT) based polymer and derivatives thereof, polyfluorene (PF) based polymer and derivatives thereof and polyspirofluorene (PSF) based polymer and derivatives thereof.

Non limiting examples of polyphenylenevinylene (PPV) based polymer and derivatives thereof, polyphenylene (PPP) based polymer and derivatives thereof, polythiophene (PT) based polymer and derivatives thereof, polyfluorene (PF) based polymer and derivatives thereof and polyspirofluorene (PSF) based polymer and derivatives thereof, which forms the exciton pinning layer or the first and second luminescent layers are MEH-PPV (poly(2-methoxy-5-(2-ethylhexyloxy)-1,4-phenylnenvinylene)), CN-PPV wherein a —CN group (a substituent which has high electron affinity) is introduced, CNMBC (conjugated-nonconjugated multiblock copolymer) where conjugation length of PPV is adjusted equally, PAT (poly(3-alkyl-thiophene), 9-alkyl-fluorene based polymer, 9,9-dialkyl-fluorene based polymer etc., but not limiting to those described above.

An organic layer of the organic light emitting device according to the present invention can comprise the luminescent layer and the exciton pinning layer as well as one or more layer selected from the group consisting of a hole injection layer, a hole transport layer, an electron blocking layer, a hole blocking layer, an electron transport layer and an electron injection layer. For example, as depicted in FIG. 1, the organic light emitting device according to the present invention can comprise a hole injection layer, a hole transport layer, a first luminescent layer, an exciton pinning layer and a second luminescent layer sequentially. Alternatively, the organic light emitting device can comprise a hole injection layer, a hole transport layer, a first luminescent layer, an exciton pinning layer, a second luminescent layer and an electron injection layer sequentially. A detailed description with regard to the hole injection layer, the hole transport layer, the electron blocking layer, the hole blocking layer, the electron transport layer and the electron injection layer can be referred to the description about a method for preparing the organic light emitting device.

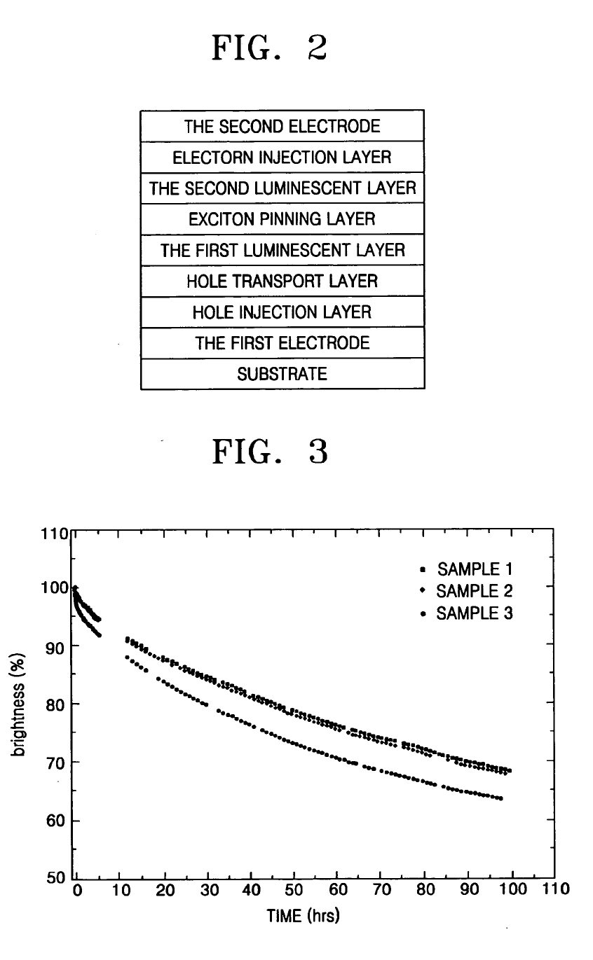

Hereinafter, referring to FIG. 2 which shows the organic light emitting device according to an embodiment of the present invention, a method for preparing the organic light emitting device according to an embodiment of the present invention will be described.

First, the first electrode is formed on a substrate, which is commonly used in an organic light emitting device. Taking account into transparency, surface leveling property, easy handling and waterproof, a glass substrate or a transparent plastic substrate can be used.

The first electrode can be made in form of a transparent electrode using highly conductive ITO, IZO, SnO₂, ZnO, In₂O₃ etc. Meanwhile, the first electrode can be made in form of a reflective electrode by forming a reflective layer with Ag, Al, Mg, Pt, Pd, Au, Ni, Nd, Ir, Cr and compounds thereof and then forming a transparent electrode layer with ITO, IZO, ZnO or In₂O₃. Those skilled in the art will recognize many modifications and variations of the electrode.

And then, the hole injection layer can be formed selectively by vacuum thermal deposition technique or spin coating technique such that it is in contact with the first electrode. There are no specific limitations for the hole injection layer material. For example, the material can include CuPc or Starburst type amines such as TCTA, m-MTDATA, HI406 (Idemitsu Co., Ltd.), soluble conductive polymer Pani/DBSA (Polyaniline/Dodecylbenzenesulfonic acid) or PEDOT/PSS (Poly(3,4-ethylenedioxythiophene)/Poly(4-styrenesulfonate)), Pani/CSA (Polyaniline/Camphor sulfonic acid) or PANI/PSS (Polyaniline)/Poly(4-styrenesulfonate) etc.

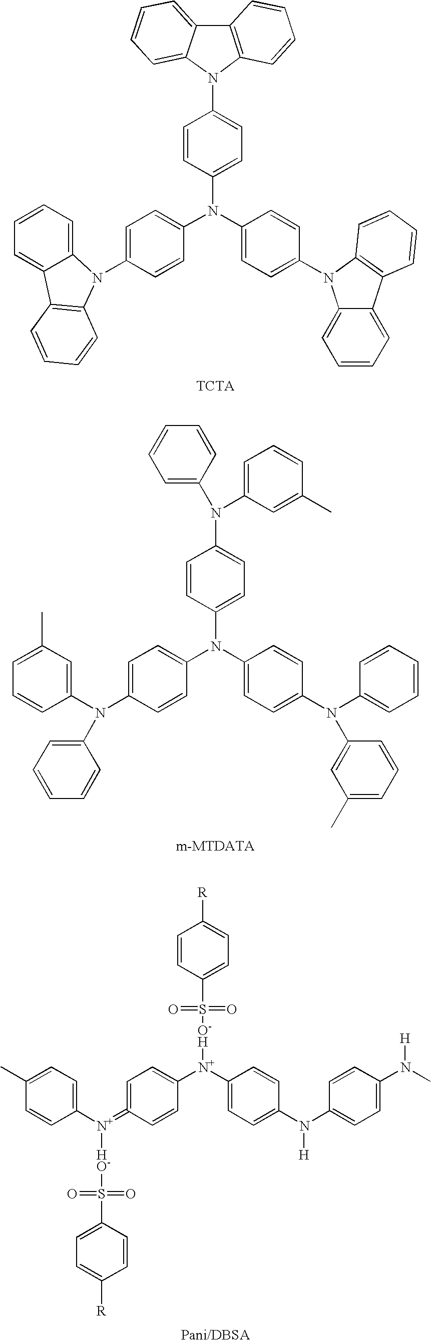

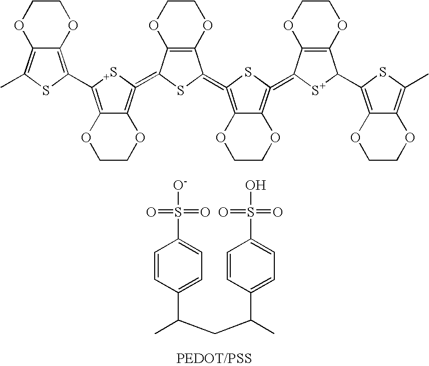

Among these, PEDOT/PSS is very stable substance of which conductivity dose not change even when it leaves in the air at 100° C. for 1000 hours. Particularly, when the hole injection layer is formed of PEDOT/PSS, the hole injection layer can be formed by solving PEDOT/PSS in water or an alcoholic solvent, and spin-coating the solution.

A thickness of the hole injection layer can be 5 nm to 100 nm, preferably 5 nm to 70 nm.

When the thickness of the hole injection layer is lower than 5 nm, it is too thin to be injected holes well. When the thickness of the hole injection layer is more than 100 nm, transmittance of light can be reduced.

And then, the hole transport layer is formed by using vacuum thermal deposition technique or coating technique such that it is in contact with the first electrode or the hole injection layer. For example, the hole transport layer can be formed by spin coating a solution composed of the materials forming the hole transport layer solved in organic solvent, wherein the organic solvent is for example dimethyl sulfoxide (DMSO), N,N-dimethyl formamide (DMF), tetrahydrofuran (THF) etc., which are well known to the those skilled in the art.

There are no specific limitations for the material forming the hole transport layer. For example, the materials can include one or more materials selected from the group consisting of compound having a carbazol group and/or an arylamine group that are served as a hole transporter, a phthalocyanine based compound and triphenylene derivatives. More specifically, the hole transport layer can be formed of one or more compounds selected from the group consisting of 1,3,5-tricarbazolylbenzene, 4,4′-biscarbazolylbiphenyl, polyvinylcarbazol, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalene-1-yl)-N,N′-diphenylbenzidine (α-NPD), N,N′-diphenyl-N,N′-bis(1-naphtyl)-(1,1′-biphenyl)-4,4′-diamine (NPB), IDE320 (Idemitse Co., Ltd.), poly(9,9-dioctylfluorene-co-N-(4-butylphenyl)diphenylamine) (TFB) and poly(9,9-dioctylfluorene-co-bis-(4-butylphenyl-bis-N,N-phenyl-1,4-phenylenediamin) (PFB) and poly(9,9-dioctylfluorene-co-bis-N,N-(4-butylphenyl)-bis-N,N-phenylbenzidine) (BFE), but not limiting to those described above.

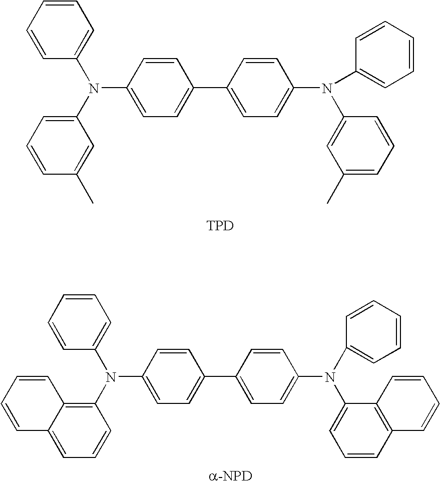

A thickness of the hole transport layer can be 1 nm to 100 nm, preferably 5 nm to 50 nm. The thickness of 5 nm to 20 nm is more preferable. When the thickness of the electron transport layer is lower than 1 nm, an ability of transporting electron can be reduced. When the thickness of the electron transport layer is more than 100 nm, a driving voltage can be increased.

And then, the luminescent layer including the first luminescent layer and the second luminescent layer, and the exciton pinning layer interposed between the first luminescent layer and the second luminescent layer are formed such that the luminescent layer is in contact with the first electrode, the hole injection layer or the hole transport layer. The materials forming the exciton pinning layer, the thickness of the layer and the like are as described above.

The luminescent layer can be formed by vacuum thermal deposition technique, coating technique etc. The coating technique includes, for example, spin coating, dip coating, spray coating and roll coating etc., but not limiting to those described above.

In an embodiment of a process for forming the luminescent layer, a coating operation can be conducted two times or more repeatedly. Preferably, the coating operation can be conducted two times or more, more preferably two, three or four times repeatedly. Herein, the coating operation of the exciton pinning layer can be conducted among a plurality of the coating operations of the luminescent layer. Also, the coating operation of the exciton pinning layer can be conducted two times or more repeatedly. Thus, the defects such as a pin hole that can be in the luminescent layer and the exciton pinning layer can be reduced. Hereinafter, a method for forming the luminescent layer will be described in reference with the operation, wherein coating operation of the luminescent layer is conducted in four times repeatedly.

First, a mixture of the material forming the first and second luminescent layers and an organic solvent is prepared. Toluene, xylene and the like can be used as the organic solvent. The concentration of the materials forming the first and second luminescent layers in the mixture can be 0.1 wt % to 1 wt %, preferably 0.4 wt % to 0.5 wt %. When the concentration of the materials forming the first and second luminescent layers is lower than 0.1 wt %, it is not sufficient for forming the first and second luminescent layers having the desired thickness. When the concentration of the materials forming the first and second luminescent layers is more than 1 wt %, surface properties of the coating film such as surface roughness can become poor, or it is difficult to repeat the coating operation. Also, a mixture of the material forming the exciton pinning layer and organic solvent is prepared as described above.

Next, the mixtures of the materials forming the first and second luminescent layers in the organic solvent is coated on the first electrode, the hole injection layer or the hole transport layer to form a first coating layer, and then a mixture of the material forming the exciton pinning layer and the organic solvent is coated on the top surface thereof, and then the mixture of the material forming the first and second luminescent layers and the organic solvent is coated on the top surface thereof to form a second coating layer. By repeating the procedure forming the second coating layer, a third coating layer is formed on the second coating layer, and the fourth coating layer is formed on the third coating layer. Finally, the final heat treatment is conducted to remove the organic solvent.

In the repeated coating operations, the organic solvent for the material forming the exciton pinning layer may solve at least a portion of the first coating layer. This phenomenon happens in forming the second coating layer, the third coating layer and the fourth coating layer as well. Thus, a pin hole and the like that can occur due to coating can be substantially prevented. After the final heat treatment operation to remove the organic solvent, the luminescent layer and the exciton pinning layer are finished. They are observed in the form of a mono-layer, not in the form of a multi-layer.

Each thickness of each coating layer can be determined depending on the thickness of the exciton pinning layer to be formed and total thickness of the luminescent layer.

In the above embodiment, the exciton pinning layer is formed on the first coating layer, but many modifications and variations are possible. For example, the exciton pinning layer can be formed on the second coating layer, the third coating layer or the fourth coating layer.

In another embodiment of method for forming the luminescent layer, a coating operation including a heat treatment operation can be conducted two times or more repeatedly. Preferably, the coating operation including the heat treatment can be conducted two, three or four times. Herein, the coating operation of the exciton pinning layer can be conducted among a plurality of the coating operations of the luminescent layer. Also, the coating operation of the exciton pinning layer can be conducted two times or more repeatedly.

Since the coating operation is accompanied by the heat treatment operation, the defects such as pinholes and the like that can occur in the luminescent layer and the exciton pinning layer due to coating are substantially prevented. Also, an orientation of the materials forming the luminescent layer can be improved, and a density can be increased. Hereinafter, the operation wherein the coating operation and the heat treatment of the luminescent layer are conducted four times will be described as an example.

First, a mixture of the materials forming the first and second luminescent layers and organic solvent is prepared. Toluene, xylene and the like can be used as the organic solvent. The concentration of the material forming the first and second luminescent layers in the mixture can be 0.1 wt % to 1 wt %, preferably 0.4 wt % to 0.5 wt %. When the concentration of the materials forming the first and second luminescent layers is lower than 0.1 wt %, it is not sufficient for forming the luminescent layer having the desired thickness. When the concentration of the material forming the first and second luminescent layers is more than 1 wt %, surface properties of the coating such as surface roughness can become poor, or it is difficult to repeat the coating operation. Also, a mixture of the material forming the exciton pinning layer and organic solvent is prepared as described above.

Next, the mixture of the materials forming the first and second luminescent layers and the organic solvent is coated on the first electrode, the hole injection layer or the hole transport layer to form a first coating layer, and then the first coating layer is heat treated at the temperature that is higher than the glass transition temperature of the materials forming the first and second luminescent layers and is lower than the thermal decomposition temperature of the materials forming the first and second luminescent layers for 10 to 60 minutes to form a first heat treatment layer. When the heat treatment is performed at the temperature higher than glass transition temperature of the material forming the first and second luminescent layers, the chain morphology of the materials forming the luminescent layer changes so that a reflective index can increase, thereby increasing the brightness of the luminescent layer. Meanwhile, when the heat treatment is conducted at the temperature lower than thermal decomposition temperature, the damage of the material forming the luminescent layer can be reduced. Alternatively, the temperature of the heat treatment is higher than the boiling point of the organic solvent, for example about 130° C., and is lower than the glass transition temperature of the material forming the first and second luminescent layers.

Next, a mixture of materials forming the exciton pinning layer and the organic solvent is coated on the first heat treatment layer, the coated first heat treatment layer is heat treated at the temperature that is higher than the glass transition temperature of the materials forming the exciton pinning layer and is lower than the thermal decomposition temperature of the materials forming the exciton pinning layer for 10 to 60 minutes, a mixture of the material forming the first and second luminescent layers and the organic solvent is coated on the top surface thereof to form the second coating layer, and then the second coating layer is heat treated in similar manner to that for the heat treatment of the first coating layer to form the second heat treatment layer. By repeating the procedure forming the second coating layer and the second heat treatment layer, the third heat treatment layer is formed on the second heat treatment layer and the fourth heat treatment layer is formed on the third heat treatment layer. Finally, the final heat treatment is conducted to remove organic solvent.

In this case, the organic solvent for the material forming the exciton pinning layer may solve at least a portion of the first heat treatment layer. This phenomenon happens in the second heat treatment layer, the third heat treatment layer and the fourth heat treatment layer as well. Thus, the pinholes that can occur in the luminescent layer due to coating are substantially prevented. Also, an orientation of the luminescent layer materials can be improved, and a density thereof can be increased. After the final heat-treating step to remove the organic solvent, the luminescent layer and the exciton pinning layer are finished. They are observed in the form of a mono-layer, not in the form of a multi-layer.

In each coating steps, a thickness of coating can be determined depending on the thickness of the exciton pinning layer to be formed and total thickness of the luminescent layer.

In the above embodiment, the exciton pinning layer is formed on the first heat treatment layer, but it can be formed on the second heat treatment layer, the third heat treatment layer or the fourth heat treatment layer.

A hole blocking layer can be formed selectively by vacuum depositing or spin coating materials on the luminescent layer. The materials for the hole blocking layer should have an ability of transporting electron and higher ionizing potential than that of a luminescent compound. There are no specific limitations for such materials. Representative examples are bis(2-methyl-8-quinolato)-(p-phenylphenolato)-aluminum (Balq), bathocuproine (BCP), tris(N-arylbenzimidazole) (TPBI) etc.

A thickness of the hole blocking layer can be 1 nm to 100 nm, preferably 5 nm to 50 nm. When the thickness of the hole-blocking layer is lower than 1 nm, it cannot display a hole blocking property effectively. When the thickness of the hole blocking layer is more than 100 nm, a driving voltage can be increased.

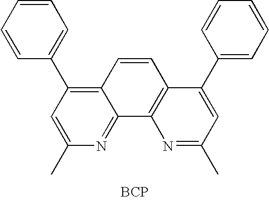

An electron transport layer is formed selectively by vacuum depositing or spin coating electron transporting materials on the luminescent layer or the hole blocking layer. There are no specific limitations for electron transporting materials. Therefore, the previously known electron transporting materials such as Alq₃, lubrene, quinoline based small molecular and high molecular compounds, quinoxaline based low small molecular compounds and polymer compounds etc. Also, they can be used alone or in combinations of two or more. The electron transport layer can be laminated by two or more other layers.

A thickness of the electron transport layer can be 1 nm to 100 nm, preferably 10 nm to 50 nm. When the thickness of the electron transport layer is lower than 1 nm, an ability of transporting electron can be reduced. When the thickness of the electron transport layer is more than 100 nm, a driving voltage can be increased.

An electron injection layer can be formed selectively by vacuum deposition technique and spin coating technique on the luminescent layer, the hole blocking layer or the electron transport layer. The materials forming the electron injection layer include BaF₂, LiF, NaF, MgF₂, AlF₃, CaF₂, NaCl, CsF, Li₂O, BaO, Liq etc., but not limiting to materials described above.

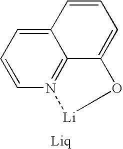

A thickness of the electron injection layer can be 0.1 nm to 30 nm, preferable 1 nm to 10 nm. The thickness of 2 nm to 6 nm is particularly preferable. When the thickness of the electron is lower than 0.1 nm, it cannot be served as an electron injection layer effectively. Also, when the thickness of the electron is more than 30 nm, a driving voltage can be increased, or an emitting efficiency can be reduced.

And then, an organic light emitting device was completed by vacuum depositing a material for the second electrode thereby forming the second electrode.

A metal used as the second electrode material include Li, Mg, Al, Al—Li, Ca, Mg—In, Mg—Ag, Ca—Al and the like, but not limiting to the metal described above and combinations thereof. Among these, for the second electrode made by two layers of Ca and Al, for example Ca layer has thickness of 2 nm to 10 nm and Al layer has thickness of 100 nm to 300 nm.

The first electrode and the second electrode can be served as an anode and a cathode respectively and vise versa. The organic light emitting device of the present invention can be used in various organic electroluminescent displays. Particularly, when it is used in active matrix organic electroluminescent display, the first electrode can be connected electrically to the drain electrode of a thin film transistor.

Although an embodiment of the organic light emitting device according to the present invention, which comprises a substrate, a first electrode, a hole injection layer, a hole transport layer, a first luminescent layer, an exciton pinning layer, a second luminescent layer, an electron injection layer and a second electrode sequentially and a method of preparing the device as depicted in FIG. 2, the present invention does not limited to those described above.

The present invention can be further illustrated by the following non-limiting examples.

### EXAMPLES

### Example 1

The first electrode was prepared by cutting 15 Ω/cm² (1200 Å) ITO glass substrate (Coming) in 50 mm×50 mm×0.7 mm, sonicating it in isopropyl alcohol and pure water for 5 minutes respectively, and then rinsing it with UV and ozone for 30 minutes. On the first electrode, a hole injection layer having thickness of 50 nm was formed by spin coating aqueous solution of PEDOT/PSS (hole injecting material manufactured by Bayer). Next, on the hole injection layer, a hole transport layer having thickness of 5 nm was formed by spin coating BFE obtained by synthesis at 2000 rpm.

Next, a mixture of TS9, which is blue luminescent material independently synthesized and xylene was obtained by mixing the TS9 and xylene. A concentration of TS9 in the mixture was adjusted to 0.4 wt %. The first coating layer having thickness of 25 nm was formed by spin coating a portion of the mixture of TS9 and xylene, and then the first heat treatment layer having thickness of 25 nm was formed by heat treating the first coating layer at 200° C. for 30 minutes. As such, the first luminescent layer was formed on the hole transport layer.

Next, a mixture of red luminescent material and xylene was obtained by mixing the red luminescent material manufactured by COVION and xylene, wherein a concentration of the red luminescent material in the mixture was adjusted to 0.4 wt %. An exciton pinning layer having thickness of 30 nm was formed by spin coating a portion of the mixture on the top surface of the first luminescent layer to form a coating layer having thickness of 30 nm, and heat treating the coating layer at 200° C. for 30 minutes.

Next, the second coating layer having thickness of 25 nm was formed by spin coating a portion of the mixture of TS9 and xylene on the exciton pinning layer, and then the second heat treatment layer having thickness of 25 nm was formed by heat treating the second coating layer at 200° C. for 30 minutes.

Next, the third coating layer having thickness of 25 nm was formed by spin coating a portion of the mixture of TS9 and xylene on the second heat treatment layer, and then the third heat treatment layer having thickness of 25 nm was formed by heat treating the third coating layer at 200° C. for 30 minutes.

Finally, the fourth coating layer having thickness of 25 nm was formed by spin coating a portion of the mixture of TS9 and xylene on the third heat treatment layer, and then the fourth heat treatment layer having thickness of 25 nm was formed by heat treating the fourth coating layer at 200° C. for 30 minutes. As a result, the second luminescent layer in the form of mono-layer, which includes the second heat treatment layer and the fourth heat treatment layer, was formed on the exciton pinning layer. As such, the luminescent layer where an exciton pinning layer was interposed was obtained.

An organic light emitting device was manufactured by, on the second luminescent layer, forming BaF₂ having thickness of 3.1 nm as an electron injection layer, and then forming Ca 2.2 nm and Al 200 nm as a second electrode. This is referred to as sample 1.

### Example 2

An Organic light emitting device was manufactured in a manner similar to that in Example 1, except that the exciton pinning layer was formed on the second heat treatment layer instead of on the first heat treatment layer. This is referred to as sample 2.

### Example 3

An Organic light emitting device was manufactured in a manner similar to that in Example 1, except that the exciton pinning layer was formed on the third heat treatment layer instead of on the first heat treatment layer. This is referred to as sample 3.

### EVALUATION

### Measurement of Lifetime

Lifetime properties of the samples 1, 2 and 3 were evaluated. The results were shown in FIG. 3. Lifetime properties of the samples 1, 2 and 3 were evaluated by measuring the brightness in a function of time, using photodiode. FIG. 3 shows a ratio of the brightness against the original brightness.

As shown in FIG. 3, the shape of the lifetime curve has changed depending on the position of the exciton pinning layer.

As described above, since the organic light emitting device of the present invention comprises an exciton pinning layer interposed between the first luminescent layer and the second luminescent layer and an excitation of the exciton formed by combining of holes and electrons in the luminescent layers is accomplished more effectively, the lifetime of the organic light emitting device can be improved significantly.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light emitting device, comprising:
a first electrode;
a second electrode; and
an organic layer interposed between the first electrode and the second electrode, the organic layer having at least a luminescent layer comprising a first luminescent layer and a second luminescent layer, and an exciton pinning layer interposed between the first luminescent layer and the second luminescent layer.

2. The organic light emitting device according to claim 1, wherein a material of the first luminescent layer and a material of the second luminescent layer are the same.

3. The organic light emitting device according to claim 1, wherein a material of the first luminescent layer and a material of the second luminescent layer are different from each other.

4. The organic light emitting device according to claim 1, a highest occupied molecular orbital level of a material of the exciton pinning layer is lower than a highest occupied molecular orbital level of the material of the first luminescent layer and a highest occupied molecular orbital level of the material of the second luminescent layer.

5. The organic light emitting device according to claim 1, wherein a lowest unoccupied molecular orbital level of a material of the exciton pinning layer is lower than a lowest unoccupied molecular orbital level of the material of the first luminescent layer and a lowest unoccupied molecular orbital level of the second luminescent layer.

6. The organic light emitting device according to claim 1, wherein a highest occupied molecular orbital level of a material of the exciton pinning layer is lower than a highest occupied molecular orbital level of a material of the first luminescent layer and a highest occupied molecular orbital level of a material of the second luminescent layer, and a lowest unoccupied molecular orbital level of a material of the exciton pinning layer is lower than a lowest unoccupied molecular orbital level of a material of the first luminescent layer and a lowest unoccupied molecular orbital level of a material of the second luminescent layer.

7. The organic light emitting device according to claim 1, wherein the first and second luminescent layers are formed of a blue luminescent material, and the exciton pinning layer is formed of a green luminescent material or a red luminescent material.

8. The organic light emitting device according to claim 1, wherein the first and second luminescent layers are formed of a green luminescent material, and the exciton pinning layer is formed of a red luminescent material.

9. The organic light emitting device according to claim 1, wherein the exciton pinning layer has a thickness of 10 nm through 40 nm.

10. The organic light emitting device according to claim 1, wherein the sum of the thicknesses of the first luminescent layer and the second luminescent layer is in the range of 50 nm through 100 nm.

11. The organic light emitting device according to claim 1, wherein the exciton pinning layer is formed of at least one selected from the group consisting of oxadiazole dimer dyes (Bis-DAPOXP), spiro compounds (Spiro-DPVBi, Spiro-6P), triarylamine compounds, bis(styryl)amine (DPVBi, DSA), Flrpic, CzTT, Anthracene, TPB, PPCP, DST, TPA, OXD-4, BBOT, AZM-Zn, Coumarin 6, C545T, Quinacridone, Ir(ppy)₃, DCM1, DCM2, Eu(thenoyltrifluoroacetone)₃ Eu(TTA)₃, butyl-6-(1,1,7,7-tetramethyljulolidyl-9-enyl)-4H-pyran (DCJTB), polyphenylenevinylene (PPV) based polymer and derivatives thereof, polyphenylene (PPP) based polymer and derivatives thereof, polythiophene (PT) based polymer and derivatives thereof, polyfluorene (PF) based polymer and derivatives thereof, and polyspirofluorene (PSF) based and derivatives thereof.

12. The organic light emitting device according to claim 1, wherein the first luminescent layer and the second luminescent layer are formed of at least one independently selected from the group consisting of oxadiazole dimer dyes (Bis-DAPOXP), spiro compounds (Spiro-DPVBi, Spiro-6P), triarylamine compounds, bis(styryl)amine (DPVBi, DSA), Flrpic, CzTT, Anthracene, TPB, PPCP, DST, TPA, OXD-4, BBOT, AZM-Zn, Coumarin 6, C545T, Quinacridone, Ir(ppy)₃, DCM1, DCM2, Eu(thenoyltrifluoroacetone)₃ Eu(TTA)₃, butyl-6-(1,1,7,7-tetramethyljulolidyl-9-enyl)-4H-pyran (DCJTB), polyphenylenevinylene (PPV) based polymer and derivatives thereof, polyphenylene (PPP) based polymer and derivatives thereof, polythiophene (PT) based polymer and derivatives thereof, polyfluorene (PF) based polymer and derivatives thereof, and polyspirofluorene (PSF) based and derivatives thereof.

13. The organic light emitting device according to claim 1, wherein the organic layer further comprises at least one of a hole injection layer, a hole transport layer, an electron blocking layer, a hole blocking layer, an electron transport layer and an electron injection layer.

14. A method for preparing an organic light emitting device comprising:
forming a first electrode on a substrate;
forming an organic layer on the first electrode by forming a first luminescent layer on the first electrode, forming an exciton pinning layer on the first luminescent layer, and forming a second luminescent layer on the exciton pinning layer; and
forming a second electrode on the organic layer.

15. The process according to claim 14, wherein at least one of the first luminescent layer, the exciton pinning layer and the second luminescent layer are formed of repeating a coating operation.

16. The process according to claim 14, wherein at least one of the first luminescent layer, the exciton pinning layer and the second luminescent layer are formed of repeating an operation composed of a coating operation followed by a heat treatment.

17. The process according to claim 16, wherein the temperature of the heat treatment is higher than the glass transition temperature of materials forming the first and second luminescent layers and is lower than the thermal decomposition temperature of the materials forming the first and second luminescent layers.

18. The process according to claim 16, wherein the temperature of the heat treatment is higher than the boiling point of an organic solvent used in the coating operation and is lower than the glass transition temperature of materials forming the first and second luminescent layers.

19. The process according to claim 14, wherein the step of forming the organic layer further comprises forming at least one selected from the group consisting of a hole injection layer, a hole transport layer, an electron blocking layer, an electron transport layer and an electron injection layer.

20. An organic light emitting device, comprising:
a first electrode;
a second electrode; and
an organic layer interposed between the first electrode and the second electrode, the organic layer having at least a luminescent layer and an exciton pinning layer, the luminescent layer comprising a first luminescent layer formed of a first material and a second luminescent layer formed of a second material, the exciton pinning layer interposed between the first luminescent layer and the second luminescent layer, the exciton pinning layer formed of a third material, the third material meeting at least one of the following conditions: (1) a highest occupied molecular orbital level of the third material being lower than a highest occupied molecular orbital level of the first material and a highest occupied molecular orbital level of the second material; and (2) a lowest unoccupied molecular orbital level of the third material being lower than a lowest unoccupied molecular orbital level of the first material and a lowest unoccupied molecular orbital level of the second material.
